(19) United States
(12) Patent Application Publication
(10) Pub. No.: US 2025/0087652 A1
(43) Pub. Date: Mar. 13, 2025

(54) STRUCTURE INTEGRATED WITH OPTICAL INTERFACE ENGINE

(71) Applicant: Taiwan Semiconductor Manufacturing Co., Ltd., Hsinchu (TW)

(72) Inventors: Wei-Yu Chen, Taipei City (TW); Cheng-Shiuan Wong, Hsinchu (TW); Chia-Shen Cheng, Hsinchu (TW); Hsuan-Ting Kuo, Taichung City (TW); Hao-Jan Pei, Hsinchu (TW); Hsiu-Jen Lin, Zhubei City (TW); Mao-Yen Chang, Kaohsiung City (TW)

(21) Appl. No.: 18/405,844

(22) Filed: Jan. 5, 2024

Related U.S. Application Data
(60) Provisional application No. 63/581,020, filed on Sep. 7, 2023.

(51) Int. Cl. H01L 25/18; H01L 21/56; H01L 23/00; H01L 23/31; H01L 23/538; H01L 25/00

(52) U.S. Cl. CPC H01L 25/18; H01L 21/56; H01L 23/3185; H01L 23/5386; H01L 24/16; H01L 25/50; H01L 24/32; H01L 24/73; H01L 2224/16227; H01L 2224/32225; H01L 2224/73204

(57) ABSTRACT

A semiconductor package includes an interposer that has a first side and a second side opposing the first side. A semiconductor device that is on the first side of the interposer and an optical device that is on the first side of the interposer and next to the semiconductor device. A first encapsulant layer includes a first portion and a second portion. The first portion of the first encapsulant layer is on the first side of the interposer and along sidewalls of the semiconductor device. A gap is between a first sidewall of the optical device and a second sidewall of the first portion of the first encapsulant layer. A substrate is over the second side of the interposer. The semiconductor device and the optical device are electrically coupled to the substrate through the interposer.

### PRIORITY CLAIM AND CROSS-REFERENCE

This application claims the benefit of U.S. Provisional Application No. 63/581,020, filed on Sep. 7, 2023, entitled “Structure Integrated with OI Engine in CoWoS-L,” which is incorporated herein by reference.

### DISCUSSION OF THE BACKGROUND

The semiconductor industry continues to improve the integration density of various electronic components (e.g., transistors, diodes, resistors, capacitors, etc.) by continual reductions in minimum feature size, which allow more components, hence more functions, to be integrated into a given area. Integrated circuits with high functionality require many input/output pads. Yet, small packages may be desired for applications where miniaturization is important.

Integrated Fan Out (InFO) package technology is becoming increasingly popular, particularly when combined with Wafer Level Packaging (WLP) technology in which integrated circuits are packaged in packages that typically include a redistribution layer (RDL) or post passivation interconnect. It is highly desirable that contact pads of the package provide high speed reliable communication.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 8 illustrate the cross-sectional views of intermediate stages in the formation of a device connection structure, in accordance with some embodiments.

FIGS. 9 and 10 illustrate the cross-sectional views for placement of a plurality of semiconductor devices over the device connection structure, in accordance with some embodiments.

FIG. 11 illustrates the cross-sectional view of de-mounting a carrier substrate from the device connection structure and mounting another carrier substrate to the device connection structure, in accordance with some embodiments.

FIG. 12 illustrates the cross-sectional view of connecting a semiconductor substrate to the device connection structure, in accordance with some embodiments.

FIGS. 13A, 13B, 14A, and 14B illustrate the cross-sectional views and top views of applying a saw to a molding over the pluralities of the through-molding vias (TMVs) to expose external device connectors under the molding, in accordance with some embodiments.

FIGS. 15A and 15B illustrate the cross-sectional view and top view of placement of an optical interface engine over exposed external device connectors of the device connection structure, in accordance with some embodiments.

FIGS. 16A and 16B illustrate a cross-sectional view of the packaged semiconductor system and a system-level diagram of the optical interface engine, in accordance with some embodiments.

FIGS. 17A, 17B, 17C, 17D, and 17E illustrate the cross-sectional views of the top portion of the device connection structure after the molding is removed to expose the external device connectors, in accordance with some embodiments.

FIGS. 18A, 18B, 18C, 18D, and 18E illustrate the cross-sectional views of the top portion of the device connection structure after the molding is removed to expose the external device connectors, in accordance with some embodiments.

FIGS. 19A, 19B, 19C, 19D, and 19E illustrate the cross-sectional views of the top portion of the device connection structure after the molding is removed to expose the external device connectors, in accordance with some embodiments.

FIG. 20 illustrates a flow diagram of a process for generating a packaged semiconductor system, according to some embodiments of the disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, the plurality of semiconductor devices, e.g., electronic devices, placed over an interposer may communicate with each other via the interposer and the semiconductor substrate. The semiconductor substrate and the plurality of semiconductor devices of the packaged semiconductor system, e.g., a packaged semiconductor device or apparatus, may also communicate with other systems. Utilizing fiber optical communication between the packaged semiconductor system and other systems may increase the communication speed and may reduce communication noise. Thus, an optical interface (OI) engine may be placed on the semiconductor substrate of the packaged semiconductor system. The OI engine may receive the electrical signals of the plurality of the semiconductor devices through the semiconductor substrate. The OI engine of the packaged semiconductor system may convert the electrical signals to optical signals and may transmit the optical signals through an optical communication conduit to the other systems. In addition, the OI engine may receive optical signals vial the optical communication conduit from other systems. The OI engine may convert the optical signals to electrical signals and then transmit the electrical signal to the plurality of the semiconductor devices of the packaged semiconductor system. In some embodiments, placing the OI engine of the packaged semiconductor system on the semiconductor substrate produces a distance between the plurality of the semiconductor devices and the OI engine. The distance can deteriorate the electrical communication, e.g., the electrical signals, between the OI engine and the plurality of the semiconductor devices and may eventually deteriorate the communication between the packaged semiconductor system and the other systems. In the embodiments described below, the OI engine of the packaged semiconductor system may be placed over the interposer next to the plurality of semiconductor devices, e.g., in close proximity to the plurality of semiconductor devices, over the interposer. The OI engine of the packaged semiconductor system may communicate with the plurality of semiconductor devices of the packaged semiconductor system via the interposer and the semiconductor substrate. Thus, the distance between the OI engine and the plurality of semiconductor devices of the packaged semiconductor system is close enough to prevent the deterioration of the electrical signals.

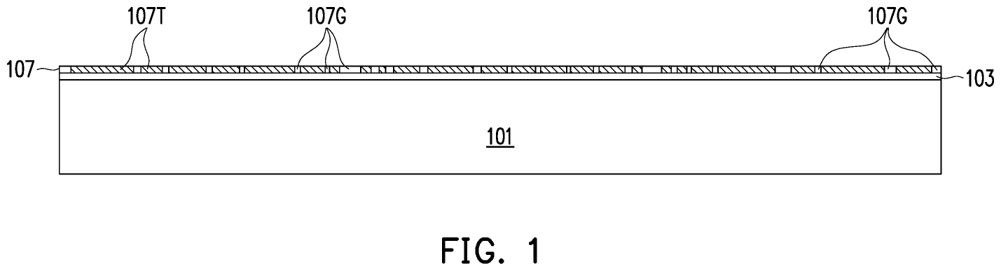

FIG. 1 illustrates a cross-sectional view of forming a redistribution layer (RDL) over a first carrier substrate 101 in an intermediate stage of forming a packaged semiconductor device, according to some embodiments. According to some embodiments, the first carrier substrate 101 has a first release film 103 coating the top surface of the first carrier substrate 101. In some embodiments, the first carrier substrate 101 is formed of a transparent material, and may be a glass carrier, a ceramic carrier, an organic carrier, or the like. The first release film 103 may be formed of a Light-To-Heat-Conversion (LTHC) coating material applied to the first carrier substrate 101 in a coating process. Once applied, the LTHC coating material is capable of being decomposed under the heat of light/radiation (such as laser), and hence can release the first carrier substrate 101 from the structure formed thereon.

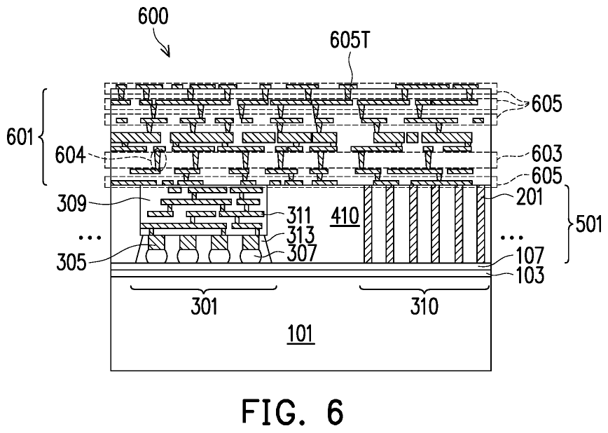

FIG. 1 further illustrates the formation of the redistribution traces 107T over the first release film 103. According to some embodiments, the redistribution traces 107T may include redistribution lines, micro-bump pad plating, combinations, or the like. The redistribution traces 107T may be formed by initially forming a metal seed layer over the first release film 103. The seed layer may include an adhesion layer and a copper-containing layer in accordance with some embodiments. The adhesion layer may be formed of titanium, titanium nitride, tantalum, tantalum nitride, or the like. The copper-containing layer may be formed of substantially pure copper or a copper alloy. The metal seed layer may be formed using a Physical Vapor Deposition (PVD), a Plasma Enhance Chemical Vapor Deposition (PECVD), an Atomic Layer Deposition (ALD), or the like. Once the metal seed layer has been formed, a plating mask (e.g., a photo resist) may be formed over the metal seed layer with openings patterned into the plating mask to expose some portions of metal seed layer. Next, the redistribution traces 107T are formed in openings of the plating mask, for example, using an electro-chemical plating technique. The redistribution traces 107T may be formed of copper, aluminum, nickel, palladium, alloys thereof, combinations, or the like. As shown in FIG. 1, a plurality of redistribution traces 107T are disposed over the first release film 103. In some locations between the plurality of redistribution traces 107T, the first release film 103 may not be covered by the redistribution traces 107T. The plurality of redistribution traces 107T may be displayed as an RDL 107 over the first release film 103 such that a gap 107G may exist at either side of the redistribution traces 107T and/or between adjacent redistribution traces 107T. The redistribution traces 107T and, thus, the RDL 107 may be formed as described below with respect to forming the RDLs of FIG. 6.

After the redistribution traces 107T have been formed, the plating mask is removed e.g., by ashing or a chemical stripping process, such as using oxygen plasma or the like, and the underlying portions of metal seed layer are exposed. Once the plating mask has been removed, the exposed portions of the metal seed layer are etched away.

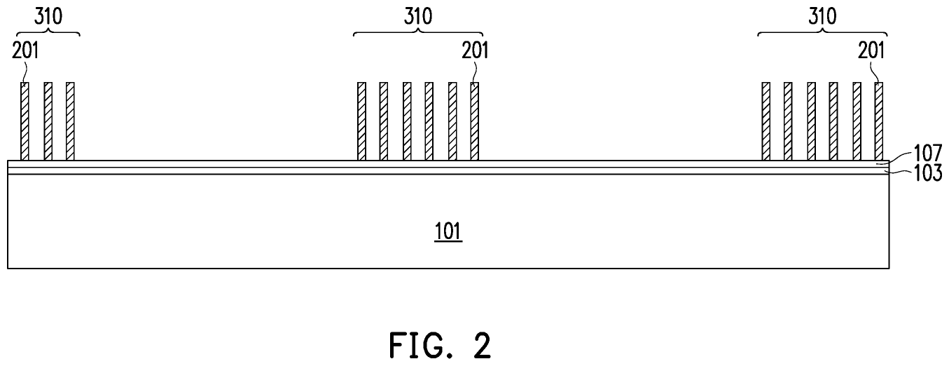

Turning to FIG. 2, through-molding vias (TMVs) 201 are formed over the RDL 107 that includes a collection of the redistribution traces 107T, in accordance with some embodiments. In an embodiment, the TMVs 201 may be formed by initially depositing a photoresist (not shown) over the redistribution traces 107T. Once the photoresist has been formed, it may be patterned to expose those portions of the redistribution traces 107T that are located where the TMVs 201 will subsequently be formed. The patterning of the photoresist may be done by exposing the photoresist in desired locations of the TMVs 201 and developing the photoresist to either remove the exposed portions or the un-exposed portions of the photoresist.

Once the photoresist has been patterned, a conductive material may be formed on the redistribution traces 107T. The conductive material may be a material such as copper, titanium, tungsten, aluminum, another metal, the like, or a combination thereof. The conductive material may be formed through a deposition process such as electroplating, electroless plating, or the like to generate the TMVs 201. However, while the material and methods discussed are suitable to form the conductive material, these are merely examples. Any other suitable materials or any other suitable processes of formation, such as CVD or PVD, may also be used to form the TMVs 201. Once the conductive material has been formed, the photoresist may be removed through a suitable removal process such as an ashing process or a chemical stripping process, such as using oxygen plasma or the like. In some embodiments, the TMVs 201 may have a height that is between about 5 μm and about 100 μm. However, any suitable height may be used for the TMVs 201.

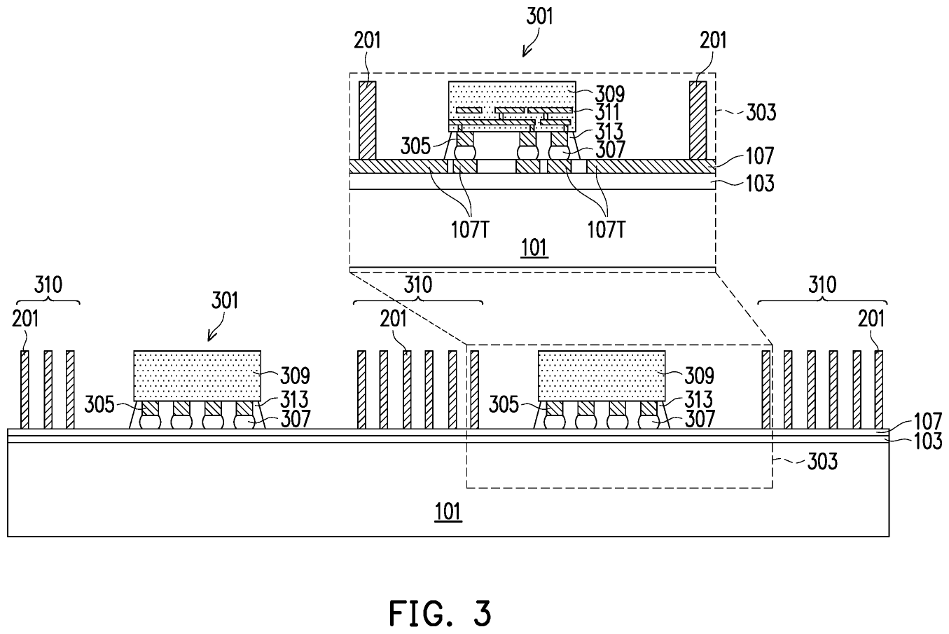

FIG. 3 illustrates the placement and attachment of interconnect devices 301 (e.g., local silicon interconnects (LSI), or the like) to the redistribution traces 107T, according to some embodiments. As noted, the interconnect devices 301 may be devices such as the LSIs, silicon buses (Si-bus), integrated voltage regulators (IVRs), integrated passive devices (IPDs), static random access memory (SRAM), combinations of these, or the like. However, any suitable devices may be utilized.

FIG. 3 further shows two of the interconnect devices 301 attached to the redistribution traces 107T, but also one or more than two interconnect devices 301 may be attached. The attached interconnect devices 301 may include multiple of similar ones of the interconnect devices 301 and/or more than one type of the interconnect devices 301. In some embodiments, other types of devices may be attached to the redistribution traces 107T in addition to the interconnect devices 301.

FIG. 3 further illustrates a section 303, in a magnified view, of the interconnect device 301 after attachment. In some embodiments, the interconnect devices 301 include conductive connectors 305, which may be used to make electrical connections to the interconnect devices 301. The interconnect devices 301 shown in FIG. 3 have conductive connectors 305 formed on a single side, e.g., bottom, of each of the interconnect devices 301, but in some embodiments, the interconnect devices 301 may have conductive connectors 305 formed on opposites sides, e.g., top and bottom of the interconnect devices 301. In some embodiments, a solder material 307 is formed on each of the conductive connectors 305 prior to attachment.

In some embodiments, the conductive connectors 305 include metal pads or metal pillars (such as copper pillars). The conductive connectors 305 may include a conductive material such as solder, copper, aluminum, gold, nickel, silver, palladium, tin, the like, or a combination thereof. In some embodiments, the metal pillars may be solder-free and/or have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In some embodiments, the pitch of the conductive connectors 305 may be between about 20 μm and about 80 μm, and the height of the conductive connectors 305 may be between about 2 μm and about 30 μm.

In some embodiments, the solder material 307 formed on the conductive connectors 305 may be ball grid array (BGA) connectors, solder balls, controlled collapse chip connection (C4) bumps, micro bumps (e.g., μbumps), electroless nickel-electroless palladium-immersion gold technique (ENEPIG) formed bumps, or the like. The solder material 307 may include a conductive material such as solder, copper, aluminum, gold, nickel, silver, palladium, tin, the like, or a combination thereof. In some embodiments, the solder material 307 is formed by initially forming a layer of solder through evaporation, electroplating, printing, solder transfer, ball placement, or the like. Once a layer of solder has been formed on the conductive connectors 305, a reflow may be performed in order to shape the material into the desired shapes.

The interconnect devices 301 may be placed on the first carrier substrate 101, for example, using e.g., a pick-and-place process. In some embodiments, once the solder material 307 of the interconnect devices 301 is in physical contact with the redistribution traces 107T, a reflow process may be performed to bond the solder material 307 to the redistribution traces 107T and thus attach the interconnect devices 301 to the first carrier substrate 101.

However, while the above described process describes using a solder bonding technique in order to connect the interconnect devices 301, this is intended to be illustrative and is not intended to be limiting. Rather, any suitable method of bonding, such as dielectric-to-dielectric and metal-to-metal bonding, combinations of these, or the like, may be utilized to connect the interconnect devices 301. All such methods are fully intended to be included within the scope of the embodiments.

According to some embodiments, each of the interconnect devices 301 may include one or more layers of electrical routing 311 (e.g., metallization patterns, metal lines and vias, redistribution layers (RDLs), or the like) formed in and/or over a substrate 309 that electrically couple two or more of conductive connectors 305 to one another. In some embodiments, the interconnect devices 301 are used to form interconnections or additional routing between other devices in a package, such as semiconductor devices, dies, chips, or the like, as discussed in greater detail below. In some embodiments, an interconnect device 301 includes one or more active devices (e.g., transistors, diodes, or the like) and/or one or more passive devices (e.g., capacitors, resistors, inductors, or the like). However, in other embodiments, an interconnect device 301 includes the one or more layers of the electrical routing 311 and is substantially free of active or passive devices. In some embodiments, the interconnect devices 301 may have thicknesses (excluding the conductive connectors 305 or solder material 307) that is between about 10 μm and about 100 μm, and the interconnect devices 301 may have lateral dimensions between about 2 mm by 2 mm and about 80 mm by 80 mm, such as about 2 mm by 3 mm or 50 mm by 80 mm. However, the interconnect devices 301 may have any suitable lateral dimensions. In some embodiments, the one or more layers of electrical routing 311 connect one or more conductive connectors 305 at one side of the interconnect devices 301 to one or more conductive connectors 305 at the opposite side of the interconnect devices 301.

The interconnect devices 301 may be formed using applicable manufacturing processes. The substrate 309 may be, for example, a semiconductor substrate, such as silicon, which may be doped or undoped, and which may be a silicon wafer or an active layer of a semiconductor-on-insulator (SOI) substrate, or the like. The substrate 309 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

The electrical routing 311 may be formed of alternating layers of dielectric (e.g., low-k dielectric material) and conductive material (e.g., copper) with vias interconnecting the layers of conductive material. The electrical routing 311 of the interconnect devices 301 may be formed of any suitable conductive material using any suitable process. In some embodiments, a damascene process is utilized in which the respective dielectric layer is patterned and etched utilizing photolithography techniques to form trenches corresponding to the desired pattern of metallization layers and/or vias. An optional diffusion barrier and/or optional adhesion layer may be deposited and the trenches may be filled with a conductive material. Suitable materials for the barrier layer includes titanium, titanium nitride, tantalum, tantalum nitride, or other alternatives, and suitable materials for the conductive material include copper, silver, gold, tungsten, aluminum, combinations thereof, or the like. In an embodiment, the metallization layers may be formed by depositing a seed layer of copper or a copper alloy, and filling the trenches by electroplating. A chemical mechanical planarization (CMP) may be used to remove excess conductive material from a surface of the respective dielectric layer and to planarize the surface for subsequent processing.

In some embodiments, the electrical routing 311 of the interconnect devices 301 may include fine-pitch RDLs having a pitch less than about 1 μm. The fine-pitch RDLs may be formed, for example, using single damascene and/or dual damascene processes, described above. By forming the electrical routing 311 having a fine pitch, the density of the electrical routing 311 in the interconnect devices 301 may be increased, thus improving the routing ability of the interconnect devices 301. In some cases, a higher density of electrical routing 311 in the interconnect devices 301 may allow a smaller amount of routing to be formed elsewhere in a package. This can decrease the size of a package, reduce the processing cost of a package, or improve performance by reducing the routing distances within a package. In some cases, the use of a fine-pitch formation process (e.g., a damascene or duel damascene process) may allow for improved conduction and connection reliability within the interconnect devices 301. In some cases, during high-speed operation (e.g., greater than about 2 Gbit/sec), electrical signals may be conducted near the surfaces of conductive components. Fine-pitch routing may have less surface roughness than other types of routing, and thus can reduce resistance experienced by higher-speed signals and also reduce signal loss (e.g., insertion loss) during high-speed operation. This can improve the performance of high-speed operation, for example, of Serializer/Deserializer (“SerDes”) circuits or other circuits that may be operated at higher speeds, e.g., high-bandwidth memories (HBM).

Furthermore, once the interconnect devices 301 have been attached, a first underfill 313 can be deposited in the gap between each of the interconnect devices 301 and the first release film 103. The first underfill 313 may be a material such as a molding compound, an epoxy, an underfill compound, a molding underfill (MUF), a resin, or the like. The first underfill 313 can protect the conductive connectors 305 and provide structural support for the interconnect devices 301. In some embodiments, the first underfill 313 may be cured after deposition.

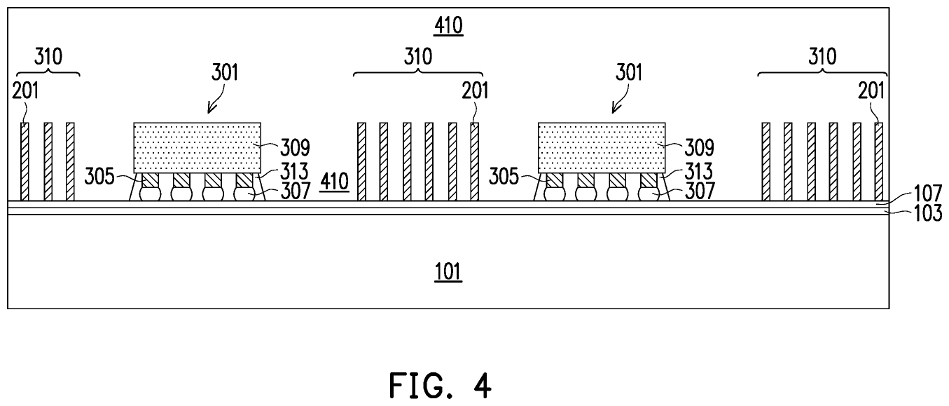

FIG. 4 illustrates an encapsulation of the interconnect devices 301 and the TMVs 201 using an encapsulant 410, in accordance with some embodiments. The encapsulation may be performed using a molding device or the encapsulant 410 may be deposited using other techniques. The encapsulant 410 may be, for example, a molding compound such as a resin, polyimide, PPS, PEEK, PES, epoxy molding compound (EMC), another material, the like, or a combination thereof. The encapsulant 410 may surround and/or cover the interconnect devices 301 and TMVs 201.

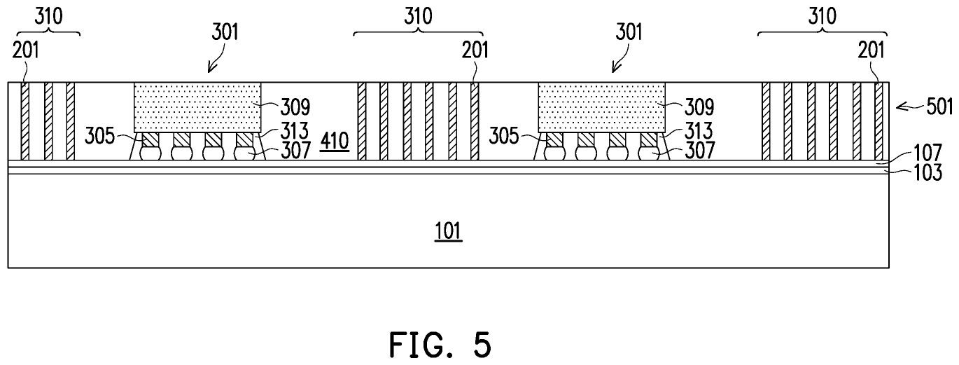

FIG. 5 illustrates a planarization process that is performed on the encapsulant 410, in accordance with some embodiments. The planarization process may be performed, e.g., using a mechanical grinding process, a chemical mechanical polishing (CMP) process, or the like. The planarization process removes excess portions of encapsulant 410 and exposes the TMVs 201. In some cases, the planarization process may also expose one or more of the interconnect devices 301. After the planarization process, the TMVs 201 and/or the interconnect devices 301 may have surfaces level with a surface of the encapsulant 410. FIG. 5 also shows an interconnect structure 501 that includes one or more interconnect devices 301 and one or more pluralities 310 of the TMVs 201 that are disposed over the RDL 107 and are covered by the encapsulant 410.

FIG. 6 illustrates the formation of a redistribution structure 600 that includes a plurality of redistribution sub-structures 601 formed over the interconnect devices 301, the TMVs 201, and the encapsulant 410, in accordance with some embodiments. The plurality of redistribution sub-structures 601 provides electrical connections to the TMVs 201. In some embodiments in which the interconnect devices 301 (e.g., the substrate 309 of the interconnect device 301) have conductive connectors 305 on a side opposite the first carrier substrate 101, the bottommost layer of the plurality of redistribution sub-structures 601 may make electrical connection to these conductive connectors 305. The plurality of redistribution sub-structures 601 includes insulation layers 603 and RDLs 605. In some embodiments, the RDLs 605 include a plurality of redistribution trances 605T and insulation layers 603 are disposed between the RDLs 605. Also included in FIG. 6 are one or more conductive vias 604 that are disposed in the insulation layers 603 between adjacent RDLs 605 to electrically connect one or more pairs of redistribution trances 605T of the adjacent RDLs 605. According to some embodiments, the plurality of redistribution sub-structures 601 may be, for example, a fan-out structure.

According to some embodiments, the plurality of redistribution sub-structures 601 includes six of the insulation layers 603 and seven of the RDLs 605. However, any suitable number of the insulation layers 603 and any suitable number of the RDLs 605 may be used to form the plurality of redistribution sub-structures 601. For example, in some embodiments, the plurality of redistribution sub-structures 601 may include between about 1 and about 15 of the insulation layers 603 and may include between about 1 and about 15 of the RDLs 605. Thus, in some embodiments, the redistribution sub-structures 601 includes the RDL 605 that is disposed over the insulation layer 603. In some embodiments, the redistribution sub-structure 601 includes an RDL 605. In some embodiments, the redistribution sub-structure 601 includes the RDL 605 coupled to an insulation layer 603.

Also, FIG. 6 illustrates that the plurality of redistribution sub-structures 601 may be formed by initially forming a first layer of the RDLs 605. In an embodiment the first layer of the RDLs 605 may be formed over desired portions of underlying conductive features, TMVs 201, and/or, if present, the conductive connectors 305 located on backsides of the interconnect devices 301. The RDLs 605 may be patterned conductive layers (e.g., metallization patterns of redistribution traces 605T) extending along the major surface of the underlying conductive features, TMVs 201, and/or, if present, the conductive connectors 305 located on backsides of the interconnect devices 301. According to some embodiments, the line portions of the RDLs 605 may have a critical dimension of between about 1 μm and about 100 μm, such as about 7 μm and the conductive vias 604 connecting the adjacent RDLs 605 may have a critical dimension of between about 5 μm and about 100 μm, such as about 25 μm.

In an embodiment, the RDLs 605 may be formed by initially forming a seed layer (not shown). In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a suitable formation process such as PVD, CVD, sputtering, or the like. The seed layer may be formed over a present layer of the insulation layers 603, in the openings of the present layer, and over the exposed features within the openings. A photoresist (also not shown) may then be formed to cover the seed layer and then be patterned to expose those portions of the seed layer that are located where the patterned conductive layer is desired to be formed. Once the photoresist has been formed and patterned, a conductive material may be formed on the seed layer. The conductive material may be a material such as copper, titanium, tungsten, aluminum, another metal, the like, or a combination thereof. The conductive material may be formed through a deposition process such as electroplating, electroless plating, or the like. However, while the material and methods discussed are suitable to form the conductive material, these are merely examples. Any other suitable materials or any other suitable processes of formation, such as CVD or PVD, may also be used to form one layer of the RDL 605. Once the conductive material has been formed, the photoresist may be removed through a suitable removal process such as an ashing process or a chemical stripping process, such as using oxygen plasma or the like. Additionally, after the removal of the photoresist, those portions of the seed layer that were covered by the photoresist may be removed through, for example, a suitable wet etch process or dry etch process, which may use the conductive material as an etch mask. The remaining portions of the seed layer of the conductive material form one layer of the RDL 605.

Once one layer of the RDLs 605 have been formed, a first layer of the insulation layers 603 is formed over the formed RDL 605. According to some embodiments, the insulation layers 603 are made of one or more suitable dielectric materials such as an oxide (e.g., silicon oxide), a nitride (e.g., silicon nitride), a polymer material, a polyimide material, a low-k dielectric material, a molding material (e.g., an EMC or the like), another dielectric material, the like, or a combination thereof. The insulation layers 603 may be formed by a process such as spin-coating, lamination, CVD, the like, or a combination thereof. However, any suitable dielectric materials and any suitable processes may be used. Furthermore, some or all of the insulation layers 603 may include the same insulating materials and/or some of the insulation layers 603 may include different insulating materials from the other layers.

In some embodiments, the insulation layers 603 are formed to thicknesses of between about 1 μm and about 50 μm, such as about 5 μm, although any suitable thicknesses may be used. Once a layer of the insulation layers 603 has been formed, openings may be formed through that layer using a suitable photolithographic mask and etching process. For example, a photoresist may be formed and patterned over the insulating layer and one or more etching processes (e.g., a wet etching process or a dry etching process) are utilized to remove portions of the insulating layer. In some embodiments, the insulation layers 603 are formed of a photosensitive polymer such as PBO, polyimide, BCB, or the like, in which openings may be patterned directly using a photolithographic mask and etching process. The openings formed in the first layer of the insulation layers 603 may expose one or more of underlying conductive layers in preparation for the deposition of an overlying one of the RDLs 605 through the openings to form conductive vias 604 and overlying conductive redistribution traces 605T.

Any suitable number of the insulation layers 603 and any suitable number of the RDLs 605 may then be formed one over the other to provide additional routing along with electrical connections within the plurality of redistribution sub-structures 601. In some embodiments, the plurality of redistribution sub-structures 601 may include different types of the insulation layers 603, such as insulating layers formed from different materials and/or different processes. In some embodiments, one or more of the insulation layers 603 may be formed of a photosensitive polymer and the other ones of the insulation layers 603 may be formed of a molding compound or encapsulant similar to the encapsulant 410. The plurality of redistribution sub-structures 601 may have any number, combination, or arrangement of different types of the insulation layers 603. However, all of the insulation layers 603 may be the same type.

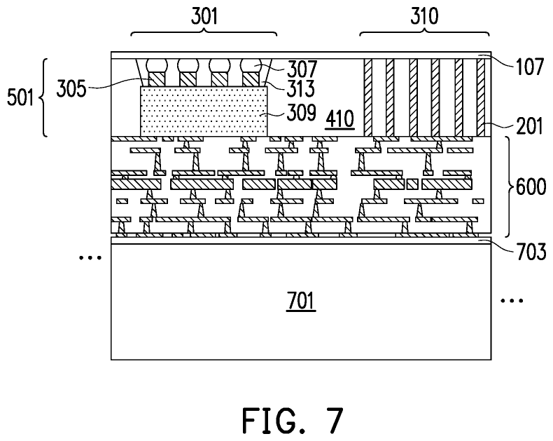

FIG. 7 illustrates the de-bonding of the first carrier substrate 101 and attachment of the redistribution structure 600 to a second carrier substrate 701. According to some embodiments, once de-bonded from the first carrier substrate 101, the redistribution structure 600 is then flipped over and bonded to the second carrier substrate 701 for further processing, or the redistribution structure 600 is bonded to the second carrier substrate 701 prior to being de-bonded. The de-bonding includes projecting a light such as a laser light or an UV light on the first release film 103 over the first carrier substrate 101 so that the first release film 103 decomposes under the heat of the light and the first carrier substrate 101 can be removed. A second release film 703 may be formed on the second carrier substrate 701 to facilitate the detachment of the redistribution structure 600 from the second carrier substrate 701. The second carrier substrate 701 and the second release film 703, may be similar to those described above for the first carrier substrate 101, and the first release film 103.

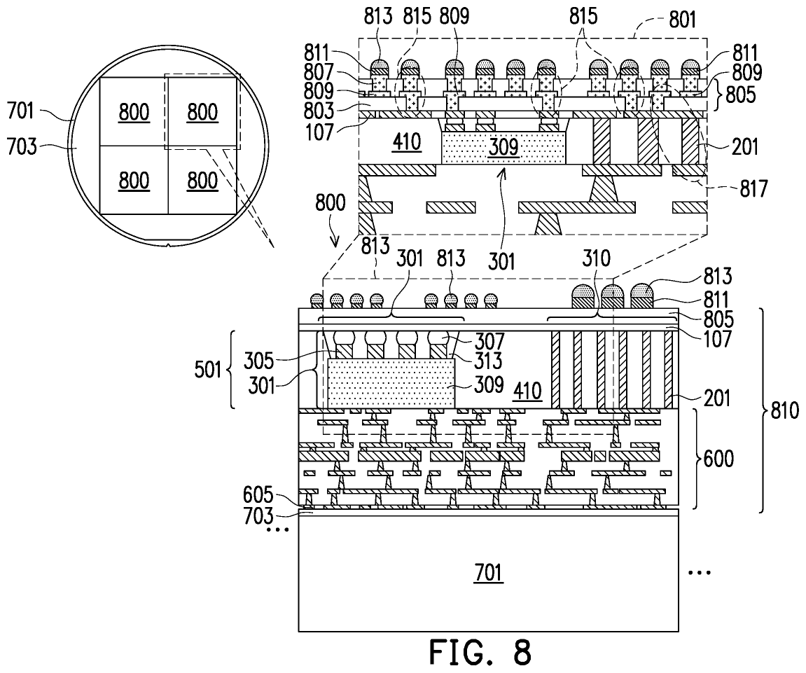

FIG. 8 illustrates a formation of a device connection structure 800 using the redistribution structure 600, according to some embodiments. FIG. 8 further illustrates, in a top down view, that a wafer forming process utilizing a circular wafer may be used to form a plurality of the device connection structures 800 and also shows an interposer 810 of the device connection structure 800. The interposer 810 includes the redistribution structure 600, the interconnect structure 501 disposed on the redistribution structure 600, and the RDL 107 disposed on the interconnect structure 501. FIG. 8 further illustrates a section 801, in a magnified view, of the redistribution structure 600.

According to some embodiments, as shown in FIG. 8, a plurality of the device connection structures 800 may be formed using wafer level processing techniques. For example, four of the device connection structures 800 may be formed over the second carrier substrate 701 in a single wafer and later singulated into the individual structures. Although an example of four of the device connection structures 800 are shown formed in the single wafer in FIG. 8, any suitable number of the device connection structures may be used.

According to some embodiments, the device connection structure 800 may be formed by initially depositing a backside protection layer 803 over the RDL 107. The backside protection layer 803 may be formed using one or more suitable dielectric materials such as polybenzoxazole (PBO), a polymer material, a polyimide material, a polyimide derivative, an oxide, a nitride, a molding compound, the like, or a combination thereof. The backside protection layer 803 may be formed by spin coating, lamination, CVD, the like, or a combination thereof. In some embodiments, the backside protection layer 803 may have a thickness between about 2 μm and about 50 μm.

Once the backside protection layer 803 has been formed, openings are formed through the backside protection layer 803 to expose areas of the redistribution traces 107T of the RDL 107 in desired locations to connect the redistribution traces 107T of the RDL 107 to a backside metallization patterns 809 through conductive vias 807. The openings may be formed in the backside protection layer 803 by forming a photoresist over the backside protection layer 803, patterning the photoresist, and etching the backside protection layer 803 through the patterned photoresist using a suitable etching process (e.g., a wet etching process and/or a dry etching process).

The backside metallization patterns 809 may be, for example, metallization patterns including conductive lines, conductive traces, conductive contacts, and/or other conductive features that combine with the conductive vias 807 to electrically connect the interconnect devices 301 and the redistribution structure 600 to external devices at the backside of the device connection structure 800. In some embodiments, a backside redistribution structure 805 may be formed using materials and processes similar to the materials and processes used for forming the redistribution structure 600. For example, a seed layer may be formed through the openings in the backside protection layer 803, over the exposed portions of the redistribution traces 107T, and over the backside protection layer 803. Once the seed layer has been formed, a photoresist may be formed and patterned on top of the seed layer in a desired pattern for the backside redistribution structure 805. Conductive material may then be formed in the patterned openings of the photoresist using e.g., a plating process. The photoresist may then be removed by ashing and the exposed portions of the seed layer may be removed by etching. As such, the backside redistribution structure 805 includes a plurality of conductive vias 807 and/or backside metallization patterns 809 are formed over the backside protection layer 803. Further backside protection layers 803 and backside redistribution structure 805 may be formed over one another until a desired topmost layer of the backside redistribution structure 805 has been formed. In some embodiments, the backside redistribution structure 805 is part of the interposer 810. Also, the device connection structure 800 includes the interposer and one or more combinations of the external device connectors 813 placed on the UBMs 811 such that the one or more combinations are arranged on the interposer 810.

According to some embodiments, the backside redistribution structure 805 includes two of the backside protection layers 803, conductive vias 807 and a single one of the backside metallization patterns 809. In some embodiments, the conductive vias 807 in the backside redistribution structure 805 may have a stacked arrangement 815 of a conductive vias 807 over a backside metallization patterns 809 (e.g., contact pad, RDL pad, or the like) that is over another conductive via 807. According to some embodiments, the conductive vias 807 may have a height of between about 2 μm and about 50 μm, such as about 5 μm. Additionally, the contact pad (the backside metallization pattern 809) between the stacked arrangements 815 may have a width that is between about 4 μm and about 40 μm, such as about 14 μm.

Furthermore, as shown in the section 801, the conductive vias 807 in the backside redistribution structure 805 that are adjacent the redistribution traces 107T may be in a staggered arrangement 817 with the TMVs 201 that are underlying the redistribution traces 107T. For example, in such a staggered arrangement 817 the conductive vias 807 are not located over an adjacent TMVs 201 to which it is connected. Rather, the conductive vias 807 are offset from the TMVs 201 by a distance, which may be between about 5 μm and about 150 μm, although any suitable distance may be utilized. In this manner, the backside redistribution structure 805 may provide electrical connections to the redistribution traces 107T, the TMVs 201, and the conductive connectors 305 of the interconnect devices 301.

Once the topmost of the backside protection layers 803 has been formed, under-bump metallizations (UBMs) 811 and external device connectors 813, e.g., connector bumps, are formed on the backside redistribution structure 805, in accordance with some embodiments. The UBMs 811 are disposed on the topmost layer of the backside protection layers 803 and form electrical connections with conductive vias 807 and/or the backside metallization patterns 809. In some embodiments, the UBMs 811 may be formed by, for example, forming openings in the topmost layer of the backside protection layers 803 and then forming the conductive material of the UBMs 811 over the backside protection layers 803 and within the openings in the backside protection layers 803. In some embodiments, the openings in the backside protection layers 803 may be formed by forming a photoresist over the backside protection layer 803, patterning the photoresist, and etching the backside protection layer 803 through the patterned photoresist using a suitable etching process (e.g., a wet etching process and/or a dry etching process).

In some embodiments, the UBMs 811 include three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the UBMs 811. Any suitable materials or layers of material that may be used for the UBMs 811 are fully intended to be included within the scope of the current application. The conductive materials of the UBMs 811 may be formed using one or more plating processes, such as electroplating or electroless plating processes, although other processes of formation, such as sputtering, evaporation, or a PECVD process, may also be used. Once the conductive materials of the UBMs 811 have been formed, portions of the conductive materials may then be removed through a suitable photolithographic masking and etching process to remove the undesired material. The remaining conductive material forms the UBMs 811. In some embodiments, the UBMs 811 may have a pitch between about 20 μm and about 80 μm.

Again referring to FIG. 8, the external device connectors 813 are formed over the UBMs 811, in accordance with some embodiments. In some embodiments, the external device connectors 813 may be ball grid array (BGA) connectors, solder balls, controlled collapse chip connection (C4) bumps, micro bumps (e.g., pbumps), electroless nickel-electroless palladium-immersion gold technique (ENEPIG) formed bumps, or the like. The external device connectors 813 may include a conductive material such as solder, copper, aluminum, gold, nickel, silver, palladium, tin, the like, or a combination thereof. In some embodiments, the external device connectors 813 is formed by initially forming a layer of solder through evaporation, electroplating, printing, solder transfer, ball placement, or the like. Once a layer of solder has been formed on the external device connectors 813, a reflow may be performed in order to shape the material into the desired shapes.

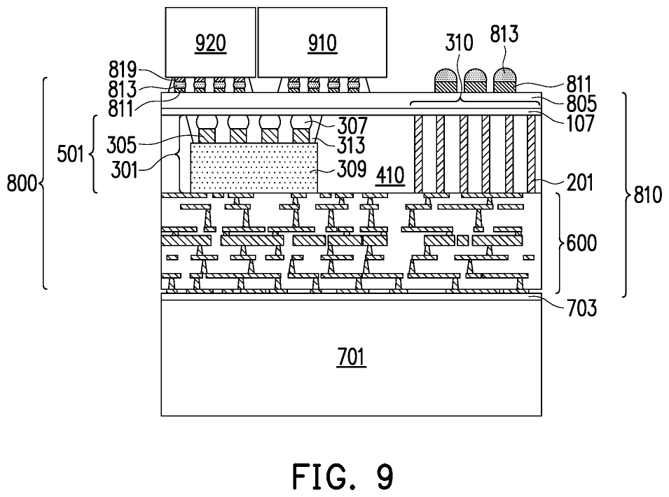

FIG. 9 illustrates the cross-sectional view of the device connection structures 800. FIGS. 6, 7, and 8 show a single device connection structure 800 from a multiple device connection structures 800 that are produced on a wafer. The circular wafer of FIG. 8 may be singulated and at least four device connection structures 800 may be produced. Thus, the device connection structures 800 of FIG. 9 is a singulated device. FIG. 9 also shows that one or more semiconductor devices, e.g., two semiconductor devices, are connected to the device connection structures 800. Thus, a first semiconductor device 920 such as an HBM, and a second semiconductor device 910, such as a system-on-chip (SoC) device are attached to the device connection structure 800. The first semiconductor device 920 and the second semiconductor device 910 have conductive connectors 819. The conductive connectors 819 of the first semiconductor device 920 and the second semiconductor device 910 are connected to the external device connectors 813 of the device connection structure 800 that are connected to the interconnect devices 301. Thus, the first semiconductor device 920 and the second semiconductor device 910 may communicate via the device connection structures 800 that includes the backside redistribution structure 805, the RDL 107, the interconnect devices 301, and the redistribution structure 600. As shown, the device connection structures 800 includes external device connectors 813 disposed on the UBMs 811. The combination of the external device connectors 813 on the UBMs 811, are disposed over the backside redistribution structure 805 and are distributed over the interconnect device 301 and the pluralities 310 of the TMVs 201. In some embodiments, the external device connectors 813 on the UBMs 811 are electrically connected, via the backside redistribution structure 805 and the RDL 107, to the pluralities 310 of the TMVs 201 and/or the interconnect device 301.

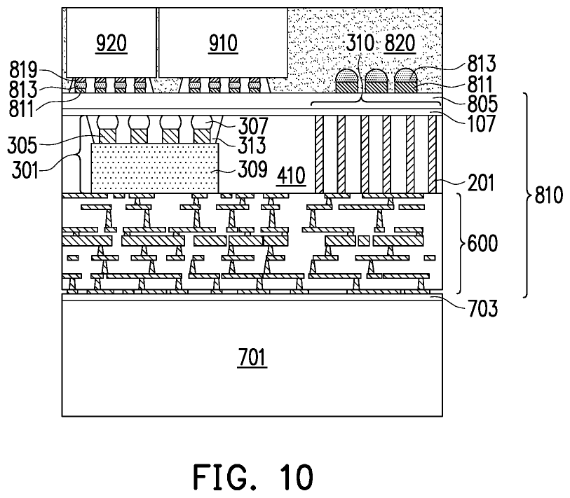

FIG. 10 illustrates the cross-sectional view of the first semiconductor device 920 and the second semiconductor device 910 that are attached to the device connection structure 800. Also, FIG. 10 shows a molding, e.g., an encapsulant layer 820, that is disposed over the interposer 810 and covers under and around up to a height of the first semiconductor device 920 and the second semiconductor device 910. The encapsulant layer 820 also covers the external device connectors 813 that are arranged on the UBMs 811 and are disposed over the pluralities 310 of the TMVs 201. The encapsulant layer 820 may be planarized or etched such that the encapsulant layer 820 over the first semiconductor device 920 and over the second semiconductor device 910 may be removed. Also, the encapsulant layer 820 over the external device connectors 813 that are arranged on the UBMs 811 becomes of the same height as the first semiconductor device 920 and/or the second semiconductor device 910. The portions of the encapsulant layer 820 over the first semiconductor device 920 and over the second semiconductor device 910 may be removed through a suitable photolithographic masking and etching process (e.g., a wet etching process and/or a dry etching process).

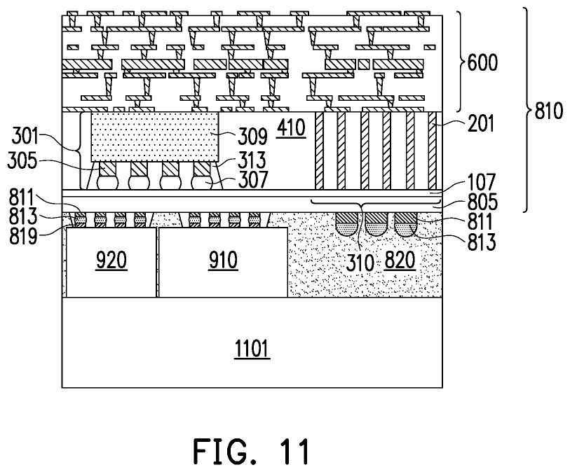

FIG. 11 illustrates the cross-sectional view of de-mounting a carrier substrate from the device connection structure and mounting another carrier substrate to the device connection structure, in accordance with some embodiments. FIG. 11 shows that the second carrier substrate 701 is demounted, the device connection structure 800 flipped, and a carrier substrate 1101 is bounded to the first semiconductor device 920, the second semiconductor device 910, and the encapsulant layer 820. Also, a side of the redistribution structure 600, opposite to the side connected to interconnect device 301, is exposed.

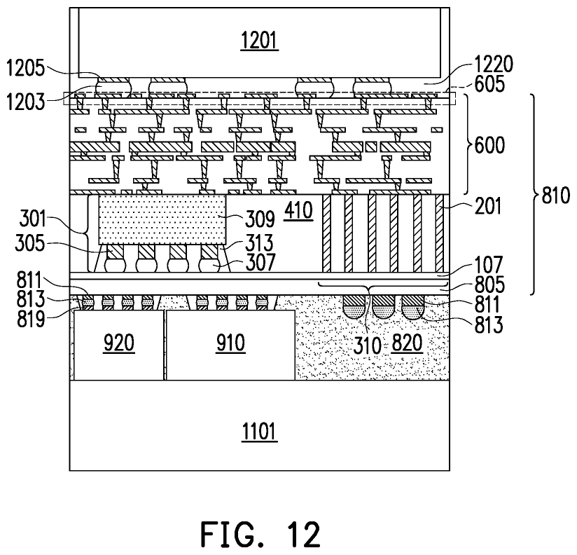

FIG. 12 illustrates the cross-sectional view of connecting a semiconductor substrate to the device connection structure, in accordance with some embodiments. A semiconductor substrate 1201 that include one or more electric-electronic circuits is connected to the exposed side of the redistribution structure 600. The semiconductor substrate 1201 is connected via conductive connectors 1205, e.g., connection pads, and external device connectors 1203, e.g., connector bumps, to the RDL 605 at the exposed side of the redistribution structure 600. The external device connectors 1203 may connect to conductive redistribution traces 605T. Then, the semiconductor substrate 1201, the conductive connectors 1205, and the external device connectors 1203 are covered by a molding, e.g., an encapsulant layer 1220.

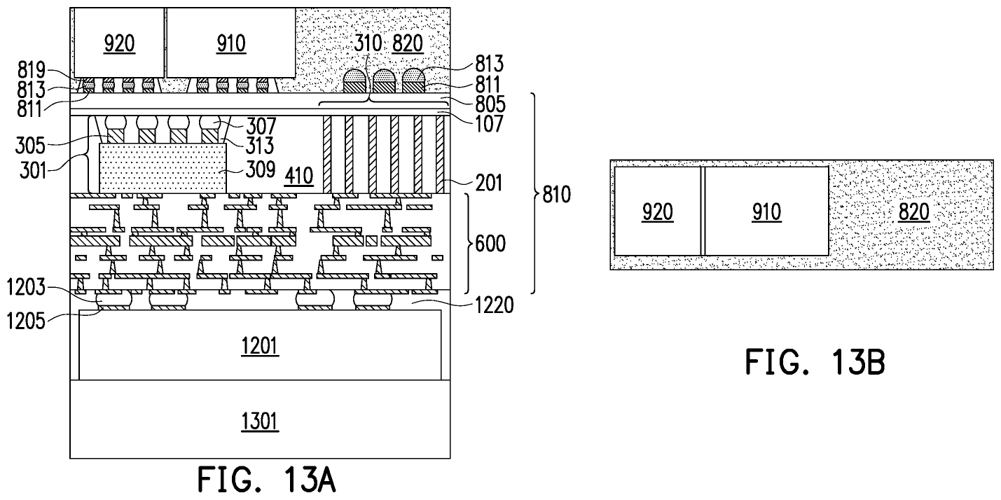

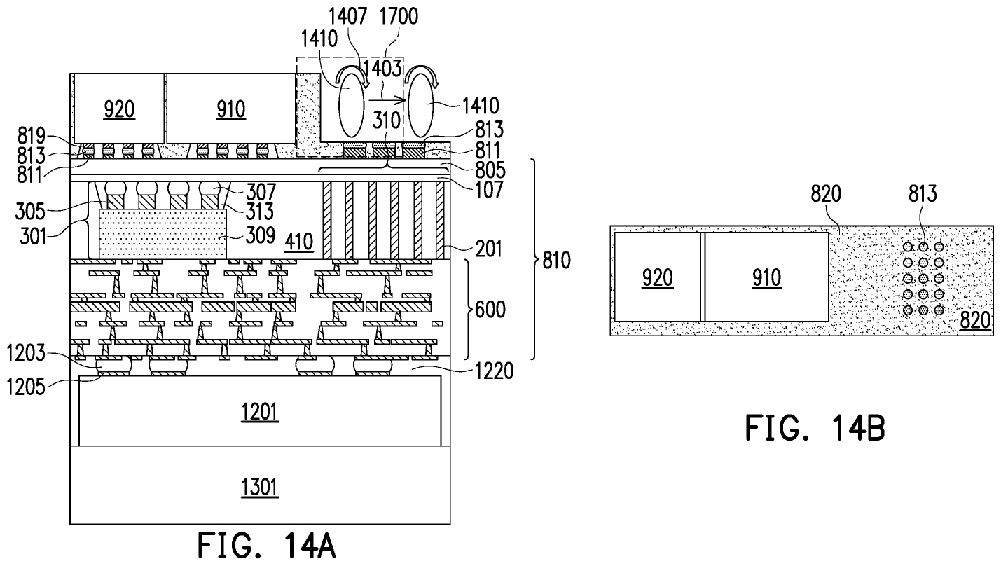

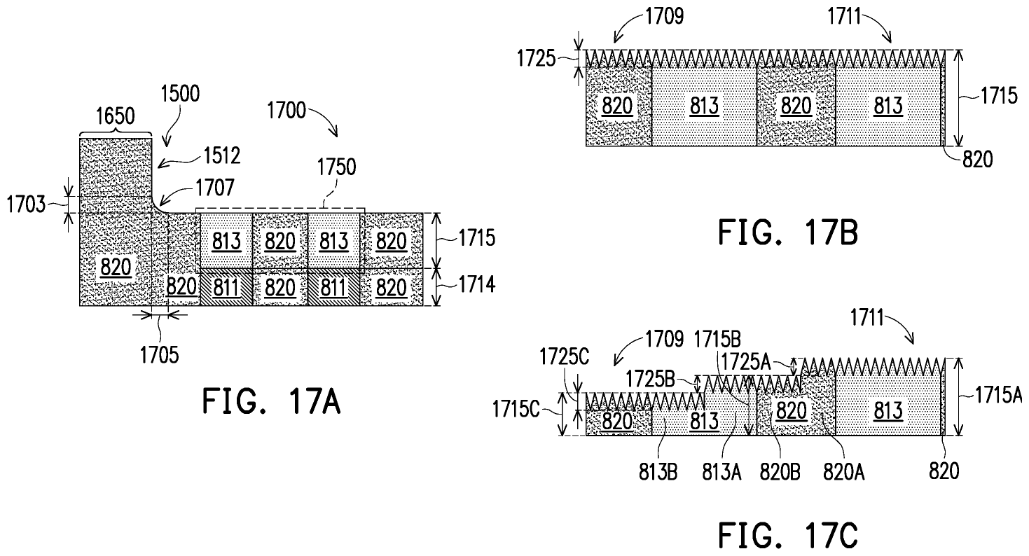

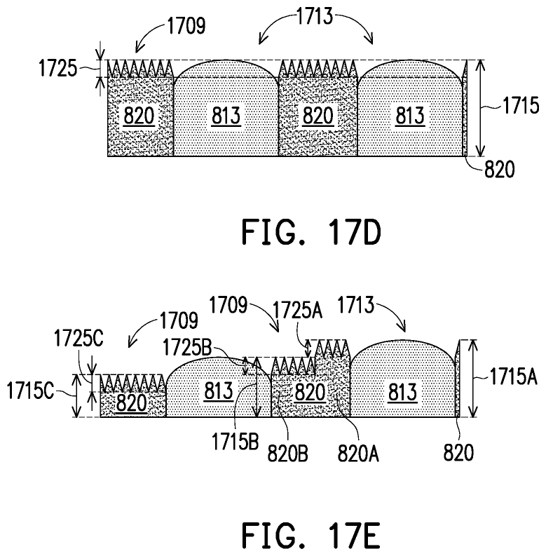

FIGS. 13A, 13B, 14A, and 14B illustrate the cross-sectional views and top views of applying a saw to a molding over the pluralities of the TMVs to expose the external device connectors 813 under the molding, in accordance with some embodiments. FIG. 13A shows the cross-sectional view of de-bonding of the carrier substrate 1101, flipping the device connection structure 800, and bonding of a carrier substrate 1301 to the semiconductor substrate 1201 and the encapsulant layer 1220 surrounding the semiconductor substrate 1201. FIG. 13B shows a top view of FIG. 13A. As shown in FIG. 10, the encapsulant layer 820 that is formed over the interposer 810 has a first portion and a second portion connected to each other. The first portion is formed, e.g., disposed, on the backside redistribution structure 805 and around and along sidewalls up to a height of the first and second semiconductor devices 920 and 910. The second portion is formed over one or more combinations of the external device connectors 813 placed on the UBMs 811 The combinations of the external device connectors 813 placed on the UBMs 811 are arranged over the plurality 310 of the TMVs 201 and are surrounded and covered by the encapsulant layer 820 that is disposed over the backside redistribution structure 805. In some embodiments, the first portion extends a distance between the first and second semiconductor devices 920 and 910 and extends around and partially under the first and second semiconductor devices 920 and 910. The second portion extends around and covers the external device connectors 813, placed on the UBMs 811, that are arranged over the plurality 310 of the TMVs 201. As shown, the external device connectors 813 are not accessible. In some embodiments, as shown in FIG. 12, the encapsulant layer 1220 covers a first surface of the semiconductor substrate 1201 that is farther from the redistribution structure 600. The encapsulant layer 1220 on the first surface of the semiconductor substrate 1201 is removed before the first surface of the semiconductor substrate 1201 is bonded to the carrier substrate 1301. FIG. 14A shows the cross-sectional view of FIG. 13A by applying a saw 1410 to the encapsulant layer 820. The saw 1410 is rotating in a direction 1407 and is moving in a direction 1403 to remove the encapsulant material of the encapsulant layer 820 and to expose the external device connectors 813 on the UBMs 811. As shown, the external device connectors 813 are exposed. Also, in some embodiments, the sawing flattens the bump of the external device connectors 813. FIG. 14B shows a top view of FIG. 14A. As shown, encapsulant layer 820 is sawed and after being sawed is recessed such that the encapsulant layer 820 is not covering the external device connectors 813. Thus, the external device connectors 813 that are placed over the plurality 310 of the TMVs 201 are exposed and the external device connectors 813 are accessible. A portion 1700 of FIG. 14A is described below with respect to FIGS. 17A, 18A, and 19A.

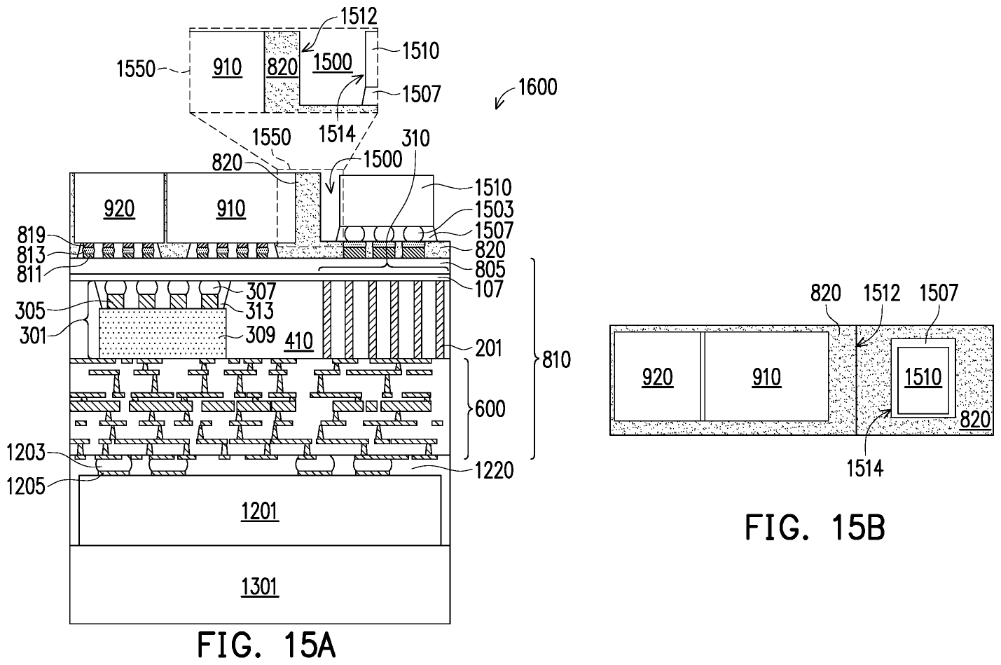

FIGS. 15A and 15B illustrate the cross-sectional view and top view of placement of an optical interface engine over exposed external device connectors 813 of the device connection structure 800, in accordance with some embodiments. FIG. 15A shows the cross-sectional view of FIG. 14A after the external device connectors 813 are exposed and an optical interface engine (OI engine) 1510 is mounted over at least a portion of the external device connectors 813. Conductive connectors 1503 that are attached to the OI engine 1510 may electrically connect to the external device connectors 813 and, thus, the OI engine 1510 may receive electrical power and electrical signals via the conductive connectors 1503 from the external device connectors 813. In some embodiments, the OI engine 1510 receives electrical power and communication signals from the electric-electronic circuits of the semiconductor substrate 1201, from the first semiconductor device 920, and/or the second semiconductor device 910. The signals may be sent and/or received via the backside redistribution structure 805 and the RDL 107, the plurality 310 of the TMVs 201, the interconnect device 301, and/or the redistribution structure 600. The OI engine may analyze the electrical signals, transform the electrical signals to optical signals, and send the optical signals to other systems. Conversely, the OI engine may receive the optical signals, transform the optical signals to electrical signals, analyze the electrical signals and send the electrical signals to the semiconductor substrate 1201, to the first semiconductor device 920, and/or to the second semiconductor device 910. As shown, a second underfill 1507 may disposed on around the conductive connectors 1503 under the OI engine 1510. The second underfill 1507 may be a material similar to the first underfill 313 that may protect the conductive connectors 1503 and provide structural support for the conductive connectors 1503. In some embodiments, the second underfill 1507 may be cured after deposition. Also, FIG. 15A shows a gap 1500 that is generated between the sidewall of the OI engine 1510 and the sidewall of the encapsulant layer 820. The encapsulant layer 820 is partially removed in the gap 1500 and over the plurality 310 of the TMVs 201 such that the second portion of the encapsulant layer 820 is recessed to expose a top surface of the external device connectors 813.

FIG. 15A further illustrates a section 1550 in a magnified view. The section 1550 shows a portion of the second semiconductor device 910, the gap 1500, and a portion of the OI engine 1510 that is arranged over the second underfill 1507. The section 1550 also shows a sidewall 1512 of the encapsulant layer 820 and a sidewall 1514 of the OI engine 1510. The sidewall 1514 also includes the sidewall of the second underfill 1507. The sidewalls 1512 and 1514 are at opposite end faces of the gap 1500. A portion of the encapsulant layer 820 is extended over the backside redistribution structure 805 at a bottom of the gap 1500 and also is extended below the second underfill 1507. In some embodiments, the first portion of the encapsulant layer 820 extends on the backside redistribution structure 805 and around the first and second semiconductor devices 920 and 910 up to the sidewall 1512. The second portion of the encapsulant layer 820, after being sawed, extends on the backside redistribution structure 805, from the sidewall 1512, along the bottom of the gap 1500, and around the external device connectors 813 that are placed on the UBMs 811.

FIG. 15B shows a top view of FIG. 15A. As shown, the second portion of the encapsulant layer 820 is removed to expose the external device connectors 813. The OI engine 1510 is placed over the external device connectors 813 such that at least a portion of the external device connectors 813 electrically connects to the conductive connectors 1503 of the OI engine 1510. Also, the second underfill 1507 is spread around the external device connectors and below the OI engine 1510 with a residual of the second underfill 1507 that is shown around the OI engine 1510 in FIG. 15B. FIG. 15B additionally shows a projection of the sidewall 1512 that is located between the first and second portions of the encapsulant layer 820 and also shows a projection of the sidewall 1514 that is located inside the second portion of the encapsulant layer 820.

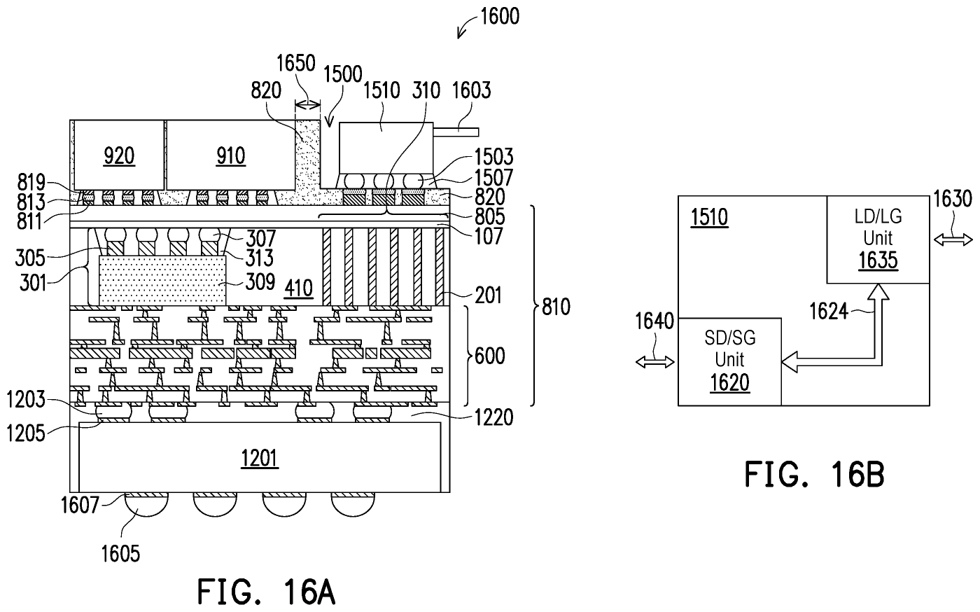

FIGS. 16A and 16B illustrate a cross-sectional view of the packaged semiconductor system 1600 and a system-level diagram of the OI engine 1510, in accordance with some embodiments. The cross-sectional view of the packaged semiconductor system 1600, a semiconductor package, shows that the OI engine 1510 is coupled to an optical cable 1603. The optical cable 1603 may be coupled to other systems to provide optical signal communication with the other systems. In addition, the semiconductor substrate 1201 is coupled via conductive connectors 1607, e.g., connection pads, to external device connectors 1605, e.g., connector bumps. In some embodiments, the packaged semiconductor system 1600 is mounted via the external device connectors 1605 to a circuit, e.g., a printed circuit board (PCB). The packaged semiconductor system 1600 may receive electrical signals, e.g., power, command, or data signals, from the other system outside the packaged semiconductor system 1600 through the external device connectors 1605. FIG. 16A additionally shows a remaining portion 1650 of the encapsulant layer 820 and the gap 1500 between the sidewall of the OI engine 1510 and the sidewall of the encapsulant layer 820, e.g., the sidewall of the remaining portion 1650 of the encapsulant layer 820.

FIG. 16B shows the system-level diagram of the OI engine 1510. The OI engine may receive electrical signals 1640 that may include power signals from the semiconductor substrate 1201, the first semiconductor device 920, or the second semiconductor device 910 via the conductive connectors 1503 of the OI engine 1510 and through the interposer 810. In some embodiments, the electrical signals 1640 are received by an electrical signal detector/signal generator unit 1620. The electrical signal detector/signal generator unit 1620 may detect and analyze the electrical signals and generate detected electrical signals 1624. In some embodiments, the electrical signal detector/signal generator unit 1620 cleans, e.g., removes the noise of, the electrical signals 1640. After the detection, the electrical signal detector/signal generator unit 1620 may perform a data check, e.g., a parity check on the received electrical signals 1640. The detected electrical signals 1624 are sent to a light detector/light generator unit 1635 to be converted to optical signals 1630. The optical signals 1630 are sent via the optical cable 1603 to the other systems. Thus, the light detector/light generator unit 1635 may include one or more light sources, e.g., light emitting diodes (LED) or laser diodes, that transform the detected electrical signals 1624 to the optical signals 1630.

Conversely, the light detector/light generator unit 1635 may receive the optical signals 1630 from the other systems, detect the optical signals 1630 by one or more light detectors of the light detector/light generator unit 1635, and generate the electrical signals 1624 that correspond to the detected optical signals 1630. The electrical signals 1624 may be sent to the electrical signal detector/signal generator unit 1620 to be sent as the electrical signals 1640, via the conductive connectors 1503 of the OI engine 1510 and through the interposer 810, to the semiconductor substrate 1201, the first semiconductor device 920, or the second semiconductor device 910.

FIGS. 17A, 17B, 17C, 17D, and 17E illustrate the cross-sectional views of the top portion of the device connection structure 800 after the molding is removed to expose the external device connectors 813, in accordance with some embodiments. FIG. 17A is the portion 1700 of FIG. 14A that is enlarged. FIGS. 17B, 17C, 17D, and 17E show a section 1750 of the portion 1700 of FIG. 14A. As shown, the gap 1500 is limited to a sidewall of the remaining portion 1650 of the encapsulant layer 820. The remaining portion of the sidewall has an arc shape, e.g., a molding arc 1707 (a curved shape), that has a vertical extent 1703 of the sidewall and a horizontal extent 1705 of the sidewall and the extents 1703 and 1705 may vary between 5 microns and 50 microns, independent of each other or similar to each other. Thus, a radius of the molding arc 1707 may have a radius that varies between 7 microns and 75 microns and the molding arc 1707 may have a thickness, perpendicular to the plane of FIG. 17A that is between 50 microns and 700 microns. Also, a height 1715 from the top of the UBMs 811 to the top of the encapsulant layer 820 and a height 1714 of the UBMs 811 are between 20 microns and 80 microns. In some embodiments, a thickness of the remaining portion 1650 of the encapsulant layer 820 is between 50 microns and 200 microns. In some embodiments, the encapsulant layer 820 that covers under and around up to a height of the first and second semiconductor devices 920 and 910 and, also, covers the backside redistribution structure 805 in the remaining portion 1650 is a first portion of the encapsulant layer 820. A remaining encapsulant material around structures that are a combination of external device connectors 813 over UBMs 811, and the remaining encapsulant material in the gap 1500, is the second portion of the encapsulant layer 820.

As shown, the sawing and removing a portion of the second portion of the encapsulant layer 820 may flattened the top of the produced encapsulant layer 820. In some embodiments, the blade of the saw has a width between 50 microns and 4000 microns and a diamond grit size that is between 2 microns and 70 microns and, thus, sawing may generate a roughness on the external device connectors 813 with a roughness 1725 that may be between 1 micron and 10 microns. In some embodiments, the roughness of a surface is determined as a root mean square (RMS) value of peaks and valleys distances to an average surface and depends on the width and thickness of the blade. As shown in FIGS. 17D and 17E, in some embodiments, only the second portion of the encapsulant layer 820 may be sawed and the external device connectors 813 are not sawed and the bump shape surface 1713 of the external device connectors 813 is preserved and has the roughness that is less than 1 micron. In some other embodiments, as shown in FIGS. 17B and 17C, both the second portion of the encapsulant layer 820 and the external device connectors 813 are sawed. The produced second portion of the encapsulant layer 820 may have different heights of 1715A, 1715B, or 1715C as shown in FIGS. 17C and 17E and the external device connectors 813 may have different heights 1715A, 1715B, or 1715C, respectively, as shown in FIGS. 17C and 17E. In some embodiments, the external device connectors 813 and/or the second portion of the encapsulant layer 820 are sawed and have rough surfaces 1709 and 1711 as shown in FIGS. 17B, 17C, 17D, or 17E. As shown in FIGS. 17C and 17E, the sawed second portion of the encapsulant layer 820 in the middle has a step shape with two different sections 820A and 820B with two different heights 1715A and 1715B, respectively. The external device connectors 813 in the middle section of FIG. 17C may have a step shape with two different sections 813A and 813B with two different heights 1715B and 1715C, respectively. In some embodiments, a difference between the heights 1715A and 1715B is between 0.5 microns and 3 microns. Also, the difference between the heights 1715B and 1715C may be between 0.5 microns and 3 microns.

In some embodiments, as shown in FIG. 17B, the external device connectors 813 and the second portion of the encapsulant layer 820 are sawed and both have a same roughness 1725. As shown in FIG. 17C, the second portion of the encapsulant layer 820 and the external device connectors 813 having the height 1715A are both sawed and have the same roughness 1725A. The second portion of the encapsulant layer 820 and the external device connectors 813 having the height 1715B are both sawed and have the same roughness 1725B. The second portion of the encapsulant layer 820 and the external device connectors 813 having the height 1715C are both sawed and have the same roughness 1725C.

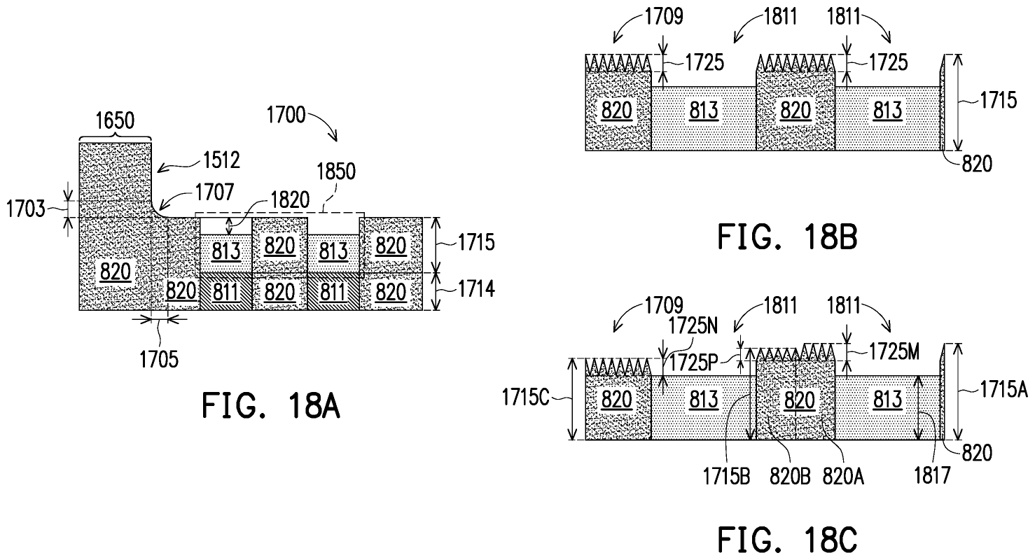

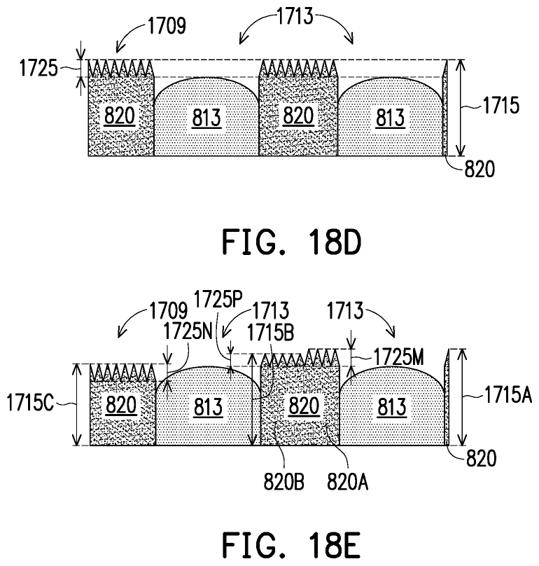

FIGS. 18A, 18B, 18C, 18D, and 18E illustrate the cross-sectional views of the top portion of the device connection structure 800 after the molding is removed to expose the external device connectors 813, in accordance with some embodiments. FIG. 18A is the portion 1700 of FIG. 14A that is enlarged. FIGS. 18B, 18C, 18D, and 18E show a section 1850 of the portion 1700 of FIG. 14A. FIGS. 18A, 18B, 18C, 18D, and 18E are very similar to FIGS. 17A, 17B, 17C, 17D, and 17E with the difference that the encapsulant layer 820 is not sawed to the level of the external device connectors 813 and after the sawing, the sawed second portion of the encapsulant layer 820 stands higher than the external device connectors 813 by a height difference 1820 that is between 1 micron and 5 microns.

As shown in FIGS. 18B and 18C, the flat shape 1811 surface of the external device connectors 813 with a height 1817 are preserved and has the roughness that is less than 1 micron. Also, shown in FIGS. 18D and 18E, the bump shape surface 1713 of the external device connectors 813 are preserved. Also, as shown in FIGS. 18B and 18D, the height 1817 of the external device connectors 813 with the flat shape 1811 surface may be smaller than the height 1715A of the encapsulant layer 80. Similar to FIGS. 17C and 17E, the second portion of the encapsulant layer 820 in the middle of FIGS. 18C and 18E has a step shape with two different sections 820A and 820B with two different heights 1715A and 1715B, respectively, and with corresponding roughness 1725M and 1725P, respectively. As shown in FIGS. 18B and 18D, the second portion of the encapsulant layer 820 has the same height 1715 and the same roughness 1725.

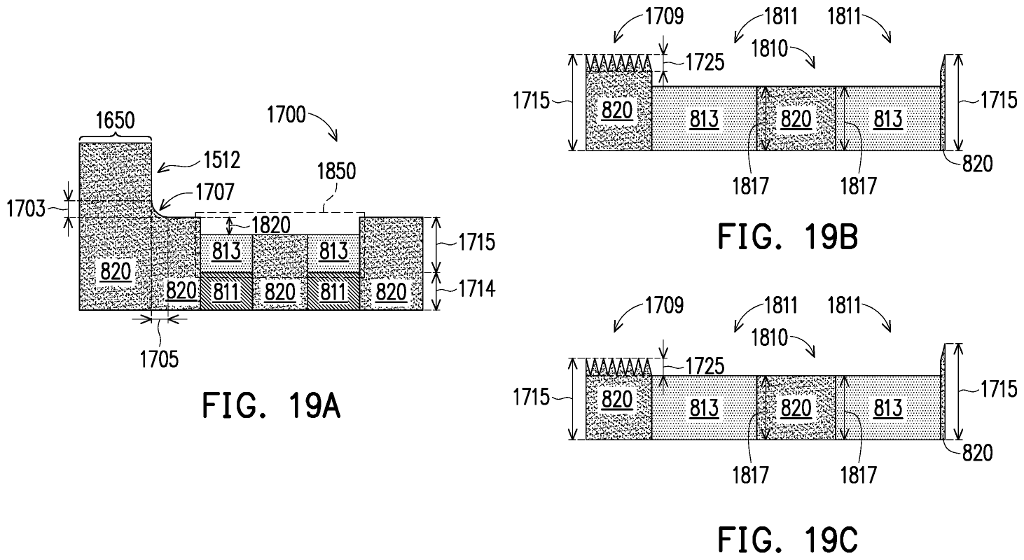

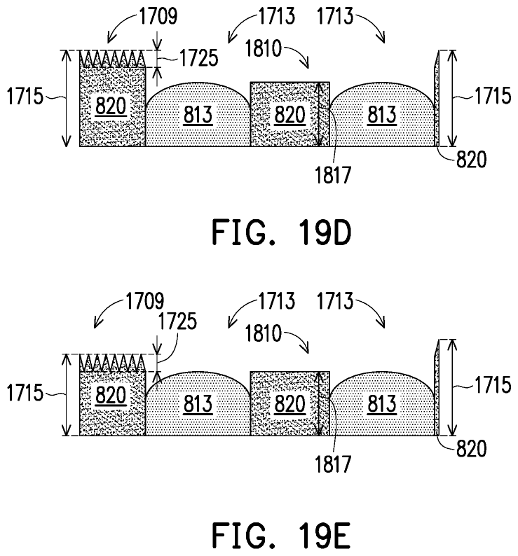

FIGS. 19A, 19B, 19C, 19D, and 19E illustrate the cross-sectional views of the top portion of the device connection structure 800 after the molding is removed to expose the external device connectors 813, in accordance with some embodiments. FIGS. 19A, 19B, 19C, 19D, and 19E are very similar to FIGS. 18A, 18B, 18C, 18D, and 18E such that the second portion of the encapsulant layer 820 at the two ends that stands higher than the external device connectors 813 by a height difference 1820, Also, with the difference that the second portion of the encapsulant layer 820 between the external device connectors 813 may have a flat shape 1810 and there is no encapsulant layer 820 with step shape. Also, the external device connectors 813 are not sawed. The second portion of the encapsulant layers 820 at both ends of the FIGS. 19B, 19C, 19D, and 19E are sawed and have the same height 1715 and the same roughness 1725.

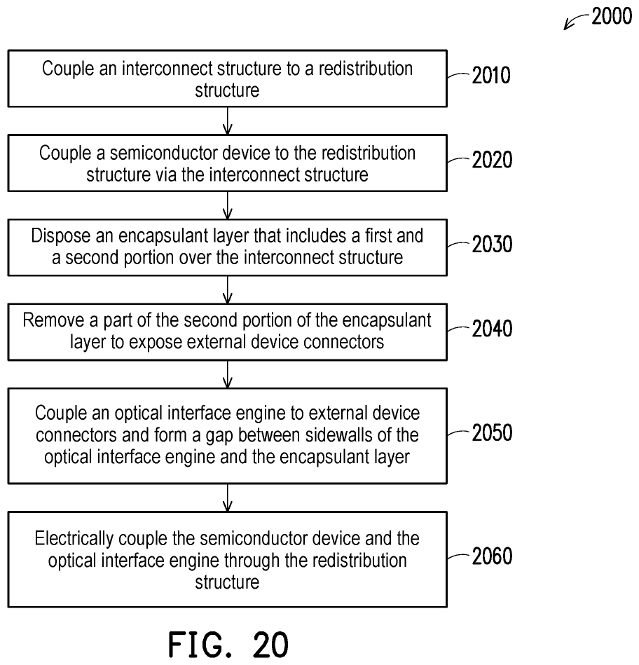

FIG. 20 illustrates a flow diagram of a process 2000 for generating a packaged semiconductor system, according to some embodiments of the disclosure. The steps of the process are shown in FIGS. 1-12, 13A, 14A, 15A, and 16A. At step 2010, an interconnect structure is coupled to a redistribution structure. As shown in FIG. 7, the interconnect structure 501 is coupled to the redistribution structure 600. The interconnect structure 501 may have a first side, opposing to, e.g., opposite to, a second side and the redistribution structure 600 may also have a first side, opposing to, a second side. In some embodiments, the first side of the interconnect structure 501 is coupled to the first side of the redistribution structure 600.

At step 2020, a semiconductor device is coupled to the redistribution structure. As shown in FIG. 9, the first electronic device, e.g., the semiconductor device 910 and/or 920 is coupled, e.g., electrically coupled, to the second side (e.g., top side in FIG. 9) of the interconnect structure 501. In some embodiments, the semiconductor device 910 and/or 920 is coupled, e.g., electrically coupled, via the first group of the external device connectors 813 and via another redistribution structure 805 to the interconnect structure 501. Also, the interconnect structure 501 may be coupled to the redistribution structure 600 and the redistribution structure 805 is coupled between the interconnect structure 501 and the semiconductor device 910 and/or 920.

At step 2030, an encapsulant layer that includes a first portion and a second portion is disposed over the interconnect structure. As shown in FIG. 10, the encapsulant layer 820 is disposed over the interconnect structure 501. The first portion of the first encapsulant layer 820 may be around the semiconductor device 910 and/or 920 and along sidewalls of the semiconductor device 910 and/or 920. The second portion of the first encapsulant layer 820 may cover the second group of the external device connectors 813.

At step 2040, a part of the second portion of the encapsulant layer is removed to expose external device connectors. As shown in FIG. 14A, the second portion of the encapsulant layer 820 is removed by the saw 1410 that is rotating in a direction 1407 and is moving in a direction 1403 to remove the encapsulant material of the encapsulant layer 820 and to expose a top surface of the external device connectors 813 that are arranged over the UBMs 811.

At step 2050, an optical interface engine is coupled to external device connectors and a gap is formed between sidewalls of the optical interface engine and the encapsulant layer. As shown in FIG. 15A, the OI engine 1510 is coupled to the second side of the interconnect structure 501. Also, a gap is formed between sidewalls of the optical interface engine and the encapsulant layer. As shown in FIG. 15, the gap 1500 is formed between the sidewall 1514 of the OI engine 1510 and the sidewall 1512 of the first portion of the encapsulant layer 820. At step 2060, the semiconductor device 910 and/or 920 and the OI engine 1510 are electrically coupled through the redistribution structure 600. Additionally, the molding arc 1707 is formed between the sidewall 1512 and the encapsulant layer 820 of the second portion of the encapsulant layer 820.

The embodiments disclosed herein can meet super high bandwidth requirements for high performance computing (HPC) applications and high bandwidth memory combined with system on integrated substrate (SoIS) solutions. As such, excellent electrical performance such as, signal integrity is achievable in a low cost packaged device. For example, in application using high speed serial/de-serial (Ser/Des) transmission protocols, these signals can be transmitted with excellent signal integrity.

As such, the packaged semiconductor system 1600 may be used in advanced networking and server applications (e.g., AI (Artificial Intelligence)) which operate with high data rates, high bandwidth demands and low latency. Furthermore, the of the packaged semiconductor system 1600 may be provided a high degree of chip package integration in a small form factor with high component and board level reliability.

According to an embodiment, a semiconductor package includes an interposer having a first side and a second side opposing the first side and a semiconductor device on the first side of the interposer. The optical device is on the first side of the interposer and next to the semiconductor device. A first encapsulant layer includes a first portion and a second portion. The first portion of the first encapsulant layer is on the first side of the interposer and along sidewalls of the semiconductor device. A gap is formed between a first sidewall of the optical device and a second sidewall of the first portion of the first encapsulant layer. The semiconductor package also includes a substrate on the second side of the interposer such that the semiconductor device and the optical device are electrically coupled to the substrate through the interposer.

In an embodiment, the second portion of the first encapsulant layer on the first side of the interposer extends from the second sidewall of the first portion of the first encapsulant layer to the optical device. The second portion of the first encapsulant layer also extends under the gap and under the optical device, and the second portion of the first encapsulant layer forms an arc shape at the second sidewall of the first portion of the first encapsulant layer. In an embodiment, the semiconductor package further includes one or more sub-structures on the first side of the interposer and under the optical device. Each one of the one or more sub-structures includes an external device connector arranged on an under-bump metallization (UBM). The one or more sub-structures are electrically coupled, via the UBM, to the interposer and the one or more sub-structures at least extend a portion of a thickness of the second portion of the first encapsulant layer. A surface of the external device connector further from the UBM is not covered by the second portion of the first encapsulant layer. In an embodiment, the surface of the external device connector has a bump shape. In an embodiment, a surface of the second portion of the first encapsulant layer between the sub-structures stands above the surface of the external device connector and has a roughness between 1 micron and 10 microns. In an embodiment, the surface of the external device connector has a flat shape.

According to an embodiment, a semiconductor package includes a first redistribution structure, having a first side and a second side opposing the first side, a first semiconductor device coupled to the first side of the first redistribution structure, an optical device coupled to the first side of the first redistribution structure. The semiconductor package further includes a first encapsulant layer that includes a first portion and a second portion such that the first portion of the first encapsulant layer is around the first semiconductor device and along sidewalls of the first semiconductor device. Also, a gap is between a first sidewall of the optical device and a second sidewall of the first portion of the first encapsulant layer facing the first sidewall. The second portion of the first encapsulant layer is on the first side of the first redistribution structure from the second sidewall of the first portion of the first encapsulant layer to the optical device. The second portion of the first encapsulant layer has a height lower than a height of the first portion of the first encapsulant layer and the second portion of the first encapsulant layer further extends under the optical device. The semiconductor package also includes a substrate coupled to the second side of the first redistribution structure. The first semiconductor device and the optical device are electrically coupled to the substrate through the first redistribution structure.

In an embodiment, the semiconductor package further includes a second semiconductor device next to the first semiconductor device and further away from the optical device than the first semiconductor device. The second semiconductor device is coupled to the first side of the first redistribution structure, and the first portion of the first encapsulant layer is around and along the sidewalls of the first semiconductor device and the second semiconductor device. In an embodiment, the first semiconductor device is a high bandwidth memory, the second semiconductor device is a system-on-chip device, and a width of the gap is between 1 and 100 microns. In an embodiment, the semiconductor package further includes a second redistribution structure coupled between the first semiconductor device and the first redistribution structure and coupled between the optical device and the first redistribution structure. In an embodiment, the semiconductor package further includes an interconnect structure disposed between the first redistribution structure and the second redistribution structure. The interconnect structure includes one or more local silicon interconnects coupled between the first redistribution structure and the second redistribution structure coupled. In an embodiment, the interconnect structure further includes a second encapsulant layer and a plurality of parallel through-molding vias (TMVs). The plurality of parallel TMVs extend in parallel through the second encapsulant layer between the first redistribution structure and the second redistribution structure. In an embodiment, the interconnect structure further includes a third encapsulant layer between the first redistribution structure and the substrate. Two or more first connector bumps extending through a thickness of the third encapsulant layer electrically couple the first redistribution structure and the substrate. In an embodiment, the first portion of the first encapsulant layer is disposed between the first redistribution structure and the first semiconductor device such that two or more connector bumps extending through the first portion of the first encapsulant layer, electrically couple the first redistribution structure and the first semiconductor device.

According to an embodiment, a method of packaging includes coupling to a first side, opposing to a second side of an interconnect structure to a first side of a first redistribution structure such that the first redistribution structure has the first side and a second side, opposing the first side, and a first group and a second group of external device connectors are coupled to the second side of the interconnect structure. The method further includes coupling a first semiconductor device to the first side of the first redistribution structure, via the first group of the external device connectors and via the interconnect structure. The method also includes disposing a first encapsulant layer that includes a first portion and a second portion over the second side of the interconnect structure such that the first portion of the first encapsulant layer is around the first semiconductor device and along sidewalls of the first semiconductor device and the second portion of the first encapsulant layer covers the second group of the external device connectors. The method includes removing a part of the second portion of the first encapsulant layer over the second group of the external device connectors to expose the second group of the external device connectors, coupling an optical interface engine to the second group of the external device connectors, and a gap is formed between a first sidewall of the optical interface engine and a second sidewall of the first portion of the first encapsulant layer, and electrically coupling the first semiconductor device and the optical interface engine through the first redistribution structure.

In an embodiment, removing the part of the second portion of the first encapsulant layer includes forming an arc shape on the second portion of the first encapsulant layer at the second sidewall. In an embodiment, the method further includes coupling a semiconductor substrate to the second side of the first redistribution structure. Also, coupling a second redistribution structure between the first semiconductor device and the first redistribution structure and coupling the second redistribution structure between the optical interface engine and the first redistribution structure. The first semiconductor device, the optical interface engine, and the semiconductor substrate are electronically coupled through the first and the second redistribution structures. In an embodiment, the method further includes forming the second portion of the first encapsulant layer between a pair of the external device connectors of the second group in step shape. In an embodiment, the method further includes forming a flat shape on a surface of the second group of the external device connectors. In an embodiment, the method further includes forming a bump shape on a surface of the second group of the external device connectors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer, having a first side and a second side opposing the first side;
a semiconductor device on the first side of the interposer;
an optical device on the first side of the interposer and next to the semiconductor device;
a first encapsulant layer comprising a first portion and a second portion, wherein the first portion of the first encapsulant layer is on the first side of the interposer and along sidewalls of the semiconductor device, wherein a gap is between a first sidewall of the optical device and a second sidewall of the first portion of the first encapsulant layer; and
a substrate on the second side of the interposer, wherein the semiconductor device and the optical device are electrically coupled to the substrate through the interposer.

2. The semiconductor package of claim 1, wherein:
the second portion of the first encapsulant layer extends on the first side of the interposer from the second sidewall of the first portion of the first encapsulant layer to the optical device, wherein the second portion of the first encapsulant layer extends under the gap and under the optical device, and wherein the second portion of the first encapsulant layer forms an arc shape at the second sidewall of the first portion of the first encapsulant layer.

3. The semiconductor package of claim 2, further comprising:
one or more sub-structures on the first side of the interposer and under the optical device, wherein each one of the one or more sub-structures comprises an external device connector arranged on an under-bump metallization (UBM), wherein the one or more sub-structures are electrically coupled, via the UBM, to the interposer and the one or more sub-structures at least extend a portion of a thickness of the second portion of the first encapsulant layer, and wherein a surface of the external device connector further from the UBM is not covered by the second portion of the first encapsulant layer.

4. The semiconductor package of claim 3, wherein the surface of the external device connector has a bump shape.

5. The semiconductor package of claim 3, wherein a surface of the second portion of the first encapsulant layer between the sub-structures stands above the surface of the external device connector and has a roughness between 1 micron and 10 microns.

6. The semiconductor package of claim 3, wherein the surface of the external device connector has a flat shape.

7. A semiconductor package, comprising:
a first redistribution structure, having a first side and a second side opposing the first side;
a first semiconductor device coupled to the first side of the first redistribution structure;
an optical device coupled to the first side of the first redistribution structure;
a first encapsulant layer comprising a first portion and a second portion, wherein the first portion of the first encapsulant layer is around the first semiconductor device and along sidewalls of the first semiconductor device, wherein a gap is between a first sidewall of the optical device and a second sidewall of the first portion of the first encapsulant layer facing the first sidewall, wherein the second portion of the first encapsulant layer is on the first side of the first redistribution structure from the second sidewall of the first portion of the first encapsulant layer to the optical device, wherein the second portion of the first encapsulant layer has a height lower than a height of the first portion of the first encapsulant layer, and wherein the second portion of the first encapsulant layer further extends under the optical device; and
a substrate, coupled to the second side of the first redistribution structure, wherein the first semiconductor device and the optical device are electrically coupled to the substrate through the first redistribution structure.

8. The semiconductor package of claim 7, further comprising:
a second semiconductor device next to the first semiconductor device and further away from the optical device than the first semiconductor device, wherein the second semiconductor device is coupled to the first side of the first redistribution structure, and wherein the first portion of the first encapsulant layer is around and along the sidewalls of the first semiconductor device and the second semiconductor device.

9. The semiconductor package of claim 8, wherein the first semiconductor device is a high bandwidth memory, the second semiconductor device is a system-on-chip device, and a width of the gap is between 1 and 100 microns.

10. The semiconductor package of claim 7, further comprising:
a second redistribution structure coupled between the first semiconductor device and the first redistribution structure and coupled between the optical device and the first redistribution structure.

11. The semiconductor package of claim 10, further comprising:
an interconnect structure disposed between the first redistribution structure and the second redistribution structure, wherein the interconnect structure comprises one or more local silicon interconnects coupled between the first redistribution structure and the second redistribution structure coupled.

12. The semiconductor package of claim 11, wherein the interconnect structure further comprises:
a second encapsulant layer; and
a plurality of parallel through-molding vias (TMVs), wherein the plurality of parallel TMVs extend in parallel through the second encapsulant layer between the first redistribution structure and the second redistribution structure.

13. The semiconductor package of claim 7, further comprising:
a third encapsulant layer between the first redistribution structure and the substrate, wherein two or more first connector bumps, extending through a thickness of the third encapsulant layer, electrically couple the first redistribution structure and the substrate.

14. The semiconductor package of claim 7, wherein the first portion of the first encapsulant layer is disposed between the first redistribution structure and the first semiconductor device, wherein two or more connector bumps extending through the first portion of the first encapsulant layer, electrically couple the first redistribution structure and the first semiconductor device.

15. A method of packaging, comprising:
coupling a first side, opposing to a second side, of an interconnect structure to a first side of a first redistribution structure, wherein the first redistribution structure has the first side and a second side, opposing the first side, and wherein a first group and a second group of external device connectors are coupled to the second side of the interconnect structure;
coupling a first semiconductor device to the first side of the first redistribution structure, via the first group of the external device connectors and via the interconnect structure;
disposing a first encapsulant layer that comprises a first portion and a second portion over the second side of the interconnect structure, wherein the first portion of the first encapsulant layer is around the first semiconductor device and along sidewalls of the first semiconductor device, and wherein the second portion of the first encapsulant layer covers the second group of the external device connectors; and
removing a part of the second portion of the first encapsulant layer over the second group of the external device connectors to expose the second group of the external device connectors;
coupling an optical interface engine to the second group of the external device connectors, wherein a gap is formed between a first sidewall of the optical interface engine and a second sidewall of the first portion of the first encapsulant layer; and
electrically coupling the first semiconductor device and the optical interface engine through the first redistribution structure.

16. The method of claim 15, wherein removing the part of the second portion of the first encapsulant layer comprises forming an arc shape on the second portion of the first encapsulant layer at the second sidewall.

17. The method of claim 15, further comprising:
coupling a semiconductor substrate to the second side of the first redistribution structure; and
coupling a second redistribution structure between the first semiconductor device and the first redistribution structure and coupling between the optical interface engine and the first redistribution structure, wherein the first semiconductor device, the optical interface engine, and the semiconductor substrate are electronically coupled through the first and the second redistribution structures.

18. The method of claim 17, further comprising:
forming the second portion of the first encapsulant layer between a pair of the external device connectors of the second group in step shape.

19. The method claim 15, further comprising:
forming a flat shape on a surface of the second group of the external device connectors.

20. The method of claim 15, further comprising:
forming a bump shape on a surface of the second group of the external device connectors.
